(19) United States
(12) Patent Application Publication
(10) Pub. No.: US 2007/0229319 A1
(43) Pub. Date: Oct. 4, 2007

(54) Electrical Coupling of an Electromechanical Control Unit

(76) Inventors: Heikki Raisanen, Jyvaskyla (FI); Jouni Mitjonen, Joensuu (FI)

Correspondence Address: KATTEN MUCHIN ROSENMAN LLP, 575 MADISON AVENUE, NEW YORK, NY, 10022-2585, US

(21) Appl. No.: 11/631,906

(22) PCT Filed: Jul. 7, 2005
(86) PCT No.: PCT/FI05/00320

§ 371 Date: May 16, 2007

(30) Foreign Application Priority Data
Jul. 7, 2004 (FI) 20040949

(51) Int. Cl. H03K 17/96

(52) U.S. Cl. 341/34

(57) ABSTRACT

An electromechanical control unit (12) that has keypad and/or touching base areas (102) to control the signal handling processing device, in the control unit (12) there is a surface element (101), by touching the surface element the changeable settings and values of the signal processing device's user are controlled. there are solid and/or variable markings on the surface element's touching area (102) that when touching them with finger or a artefact and/or when sliding on them, the values of the changeable parameters of the signal-controlling unit can be controlled or value decisions are made, which control unit is it least by part made of dynamic active material, a charge or voltage is created between the electrodes arranged on the surface of the material when the force targeted to it changes, the place and/or the amplitude being calculated with a microprocessor, micro controller or with a corresponding processor and with the received information the mentioned changeable parameter values being changed or value decisions are made, and that it includes at least three or more sensor areas (108) and the areas reacting to the touching of the sensor areas (102), corresponding signal electrodes (106) are connected to each other with capacitor (110) and the areas connected to each other are connected to the preamplifiers at least from their outer areas (109).

The invention is meant to be used in different electromechanical keypads and slide controller based on capacitive electric bubble film and also in control units in witch a wanted action is adjusted on the pad or screen by a touch of a moving finger, for example the volume of sound or the brightness of light and by touching a certain point, a particular number value or a letter is chosen for example.

### BACKGROUND OF THE INVENTION

The pads that are based on the electric mechanical film are known from the U.S. Pat. No. 5,917,437 among others. In this patent, a pad construction that holds hard hits is presented. Under the solid and hard surface there is a sensor element that has kind of a pad that has screen-printed silver paste figuration. It has presented that in the invented structure a capacitive, so called electret bubble film has been used. This electret bubble film has been presented in the U.S.- patent review 4,654,546. Electret bubble films are usually foamed die-electric plastic film made of flat and/or torn up gas blisters or cells that are charged in a powerful electrical field. The electrec bubble film has traditionally been made of polypropylen but it can also be made out of plastic material such as PEN, PET and COC mixes. It is also known that the electric bubble film gets swelled in the direction of thickness. Because of this a larger inner electrical field is formed to it while charging and it's sensitivity grows multiple times comparing to the corresponding film that hasn't been swelled. The electric bubble film is produced and sold under the wellknown brand Emfit®.

An electrical coupling that is used with the already mentioned electric bubble film has been known in the electromechanical control units according to this invention, wherein several sensor elements are resistive connected to a line (series) by the use of printed resistive conductor or separate resistors. The idea of such use of resistive connection is that when for example a sensor area that is made of five sensor areas is touched from a wanted spot, a signal (charge) corresponding to the touch is seen in a different size with the preamplifier connected to the ends of the lines. As an exception the signal is seen with the same size when the sensor area in the middle is touched. This way it has been possible to determine which spot has been touched by for example calculating with a micro controller. According to this information it is possible to control a device or the lights to witch the pad is connected to. The resistive connecting is borrowed to the electro mechanical control units made of eletric bubble films from pads that have been made of piezo electric pvdf-material or piezo crystals. Piezo electrical pvdf-materials and piezo crystals are very different in their principals of use. They are not capacitive in the same way as the electric bubble film in which the change of thickness generates a so-called mirror charge between the electrodes arranged to it. In the case of piezo electric pvdf-materials and piezo crystals, the electrical charge, produced by them in the squeeze, is based on the so called change of the position of the dipoles in a way that their poles with same signs get closer or further away from each others. In general the electric bubble film and piezo electric materials are called active materials.

### SUMMARY OF THE INVENTION

The goal of this invention is to solve the problems related to a known technique, specially in the use of capacitive electric bubble film and a new type of electrical circuit, in which a wanted amount of sensor areas are connected to a line by using suitable size capacitor between the different areas. And a new mathematical signal-processing algorithm that adjusts the sensibility to touch suitable to the user without concerning the thickness of the surface film or the possible weakening of the charging level because of the possible high temperature. Because the electric bubble film is capacitive and not resistive, the circuit frequency response remains straight in the band pass area by using capacitors instead of resistors. This makes it possible to count the relation of the signals that show with preamplifier more easily and accurately than by using the resistors.

A typical characteristic to electric bubble film is that it gets less sensitive if it exposes to temperature of over 60 Celsius degrees for a longer time. Another characteristic of this invention is a suitable algorithm in the micro controller and/or in the signal processor part belonging to the electronics of the control unit. With the algorithm the user can adjust, from the user interface of the device, the keypad and the touching feel suitable to him self or to the thickness of the surface film. The adjustment can also be automatic.

A third characteristic of the invention is the temperature default integrator algorithm. With this algorithm the strength of the device's preamplifier is automatically raised and the key pad sensitivity of the device is kept the same even though the device gets exposed to high temperature for longer times and the sensitiveness of the electric bubble film got weaker.

The characteristics of the invented control unit are presented with a more detail way in the independent claims.

### SHORT DESCRIPTION OF THE FIGURES

In the following the invention is depicted in more details with the help of figures.

FIG. 1 presents the invention's control units electrical circuit.

FIG. 2 presents the invention's control unit.

FIG. 3a presents a cross section of one of the invention's adaptation.

FIG. 3b presents a control unit of picture 3a in three dimensional, explosion picture.

FIG. 4 is a block diagram showing an algorithm for regulating the touch sensitivity.

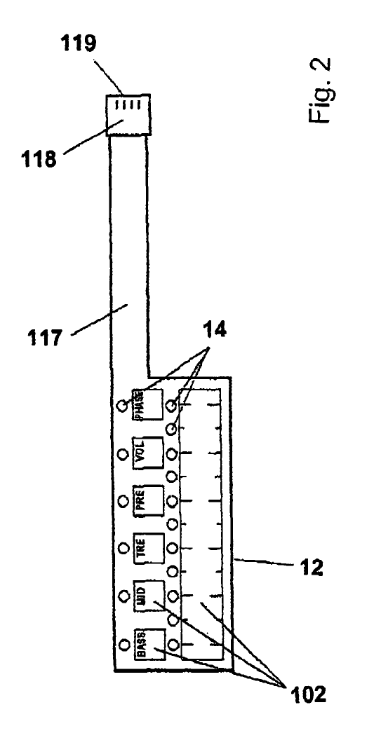

In the FIG. 2 one of the invented control units 12 is seen from the up side. With the help of leds' 14 the user is given visual information about the functions and their settings. Pressed symbols 102 tell what spot to touch to set different functions.

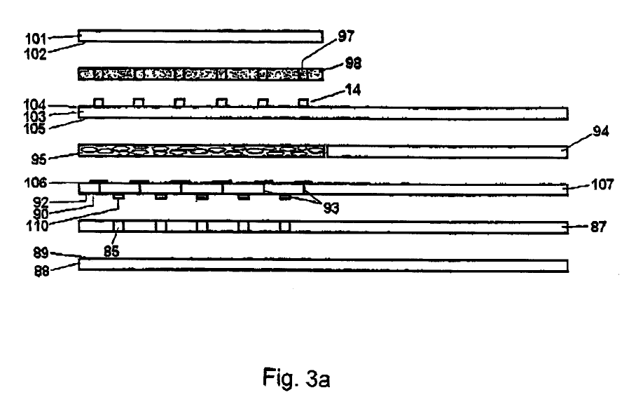

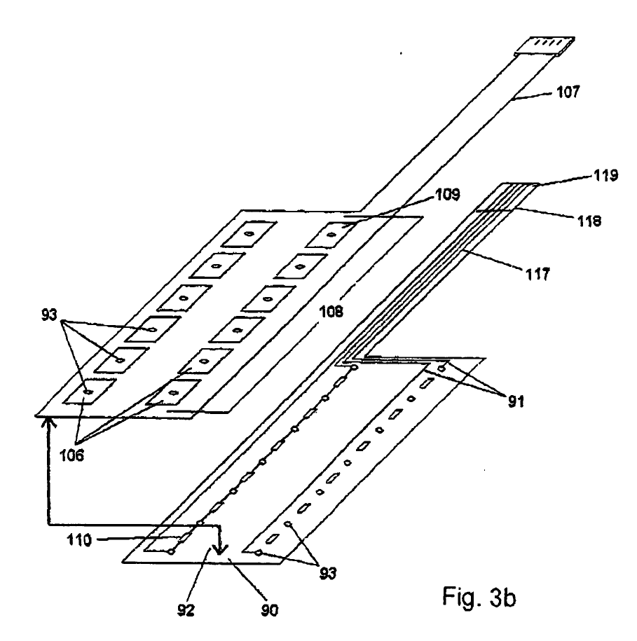

In the cross section in the FIG. 3a and in the 3D explosion figure in the FIG. 3b, the different layers of a touch sensitive control unit of thickness class 2 mm are shown. The outer surface layer 101 is economically even, use enduring, flat surface that is for example class 0.10 mm thick polyester. Surface layer 101 can also be made of silicon casting or transfer molded plastic, a hard or flexible element into which bump or grooves are arranged to give a better feel to the user of which spot to touch.

Under the lower surface of film 101 symbol FIGS. 102 of the touching base are screen-printed. Next there is thin plastic film in the element, layer 103, made of polyamide or polyester for example. Into the higher surface 104 of the layer 103 the leds' 14 conductors are arranged, either by etching or screen-printing. Because the leds 14 are even in their thinnest class 0.2 mm thick, it is good to arrange something appropriately thick and flexible between the films 101 and 103. It can also be soft like film 98 made of cell plastic that has holes 97 arranged to the place of leds 14. To the lower surface of film 103 a ground electrode figuration 105, that covers the whole area, is arranged. Further going down, the next thing is an electro mechanical film 95, which is by recommend Emfit®-film. The use and the characteristics of the film are more closely depicted for example in the WO review (U.S. Pat. No. 6,078,006 and U.S. Pat. No. 6,242,683). Next to the film 95 there is a isolation 94 that can be arranged also by screen-printing. In the following structure there is an Emfit-film's signal electrode figuration 106 arranged on the upper side of plastic film 107 that can also be a thin circuit board. This layer is presented more closely in FIG. 3b. The signal electrode figuration can be precisely in a wanted form and different areas can be rectangular, oval or round. The signal electrode figuration consists of areas 106 and when pressing these areas the element recognise the press by producing a charge impulse. The succeeding touching areas 106 that are made to the element are making the lines 108 in which the areas 106 are slightly narrower than the width of finger, and the areas are very close to each other, economically class 0.5 mm. The line's 108 purpose is to create a sensor matrix that recognise on what spot of the line to press as well as the moving of the finger according to the direction of the line. The purpose of this is to adjust a wanted function, for example the brightness of lights to brighter or dimmer. The special thing about the invention are the line's 108 small size surface connection capacitor 110 that are arranged between every area and only the outer areas 109 of the line are connected to preamplifiers and from there on to the micro controllers.

When wanted the layer 107 can therefor be made of either thin plastic film such as polyester or polyamide, or thin circuit board material. A hole 93 Is nevertheless arranged in the place of every area 106, from which all the areas are electrically connected to the lower surface 92. All of the electrodes 91 are arranged to the lower surface 92 to be connected to the preamplifier. A see trough isolation layer 90 is arranged by screen-printing on the top of connecting pins to the lower surface 92. The ground level 89 is necessary for a disturbance cover. It can be pressed on top of the isolation 90 or it can be arranged on top of it's own plastic film 88. If the used capacitor 110 are high, is recommended to use a level such as 87 under the level 107. The level 87 is economically corresponding like the level 98 which means that there are holes 85 made to It so that the resistors would not cause swelling. All the necessary conductors 91 are arranged as a ribbon 117 into one place and in the end of the ribbon 118 the connectors 119 are crimped for the connecting to the preamplifiers.

All of the electronics can be arranged to the same structure if wanted. All of the electronics required by the signal-handling unit is managed to fit to the lower surface 92 by arranging sufficiently space. Also in this case a multiple layer structured circuit board has to be used to substitute the layer 107 and a disturbance cover needed by the Emfit® film has to be arranged to the middle layer of the circuit board.

The surface film 101 can be, if wanted, to be replaced with a so called OLED (organic light emitting display)-display. They are thin, film-like display. With a help of this, all the symbols are changeable and a multi level interface can be arranged. The benefits of this are for example that in the ground state only the most important adjusters are shown big and if wanted, a single action can be set separately, the action is chosen from the user interface and the display will change into the desired one. Display, if the device is placed on a straight surface, Can also be a traditional LCD display. They can also be so thin that from a press a pressure is created so exactly that a so called cross-coupling wont occur. In addition to this, when using the Emfit® electret bubble film, which is very sensitive to squeeze but not really to bending, the cross-coupling problem is anyway low.

Between the different film layers, a glue suitable to the purpose, is used, which is very liquid and well running in a economical manufacturing method, so it is possible to spread it on top of the film's surfaces from roll to roll laminating with a so called raster-cylinder and in sheet laminating with a brush for example. Glue-material film can also be used in the purpose, which is manufactured for example by 3M. The laminating can by part be made with sheet laminating and by part with roll to roll. In the enclosed claims the laminating, targeting and cutting of different layers is explained more closely.

Like it has been told, the areas 106 of the lines 108 are connected to each other with capacitor and only the outer areas with connectors 119 to the circuit board from which they are connected to a suitable preamplifier and from there to micro controllers. Because of the capacitor 110 between the electrode areas, when pressing the singular area 106 a amplitude of the charge caused by the pressing is seen in the preamplifier in different sizes, depending from which place of the line 108 the area 106 was. This way the separately pressed spot can be calculated with micro controllers, for example with Microchip PIC16F88-I/SO and to guide an action according to it With this kind of connection the amount of needed preamplifiers is possible to keep low and the price of the electronics cheap. It is necessary to understand that this is just an example of the arranging of electronics and that it's connection pattern can alter even considerably depending on what kind of functions and how wide adjustment possibilities are wanted in the limits of enclosed claims.

The voltage corresponding to the pressing is directly comparable to the strength of the pressing when using an electrically charged Emfit® electret bubble film as a sensor film. In this case an amplitude of voltage can also be used to direct the functions of the device. For example a powerful blow in a certain location is changing the function to something other than a weak press.

Because in the element according to the invention an electrically charged electret bubble film is used as a sensor film, from the influence of every pressing a voltage is created between the signal electrodes and the ground level. This voltage can be rectified with a rectifier and to lead to the battery of the device so that the operation time Of the battery gets longer in the same charging. Furthermore into the device, for example to it's outer surfaces, sensor elements, produced in corresponding manner, can be placed. These sensor elements are used only to produce a voltage when touching the device and then to rectify them to the device's batteries. Conveniently there is several sensor films in these elements, for example 5 or 10 sensor films over lapped, for example half of them opposite to each other.

If a device where the pad based on the efectret bubble film and/or touching base is located, gets often exposed to hard heat, its sensitivity gets weaker. That causes a worsening of the pad's keypad feel (requires a harder press). There can be a processor in the device with which the matter is fixed automatically with a help of a suitable algorithm. A temperature counting sensor can be placed into the device for example and from the information received from it (temperature and time), for example when a certain threshold is exceeded that can be 50° C., the algorithm begins automatically to fix the amplifier of the preamplifier. The greater and longer the temperature, the greater the fix of the preamplifier. For example the transducer of the algorithm that describes the exposure to warmth (saved to the eeprom or to some similar non-fading memory), is enlarged the faster the more the warmth is exceeding some border. From this value it is then possible to estimate the sensitivity of the sensor according to which the basic setting of the amplifier is adjusted. This means that one of the registers is enlarged when the temperature is higher than a certain value according to how much that value is exceeded with. This is done in certain time periods, for example four times an hour. The use of the energy is managed to remain low when it's done so that the device wakes up for example every fifteen minutes in order to take an example of the temperature and to perform integration. The event takes milliseconds. There are timers in many processors that keep on rolling when the processor is put to low energy state. When the timer goes to zero it wakes up the entire processor -often even in a way that it directly moves to run the cancelling routine, where the temperature damage integrator would be. The terminal time constant of the device's warmth sensor has to be big enough, which means it is attached to the piece that has enough warmth charging ability. There can be an automatically calibration amplifier in the pad. The device can monitor what kind of signals are coming from the pad and it changes the amplifier according to it with small changes. There also is a mix of these two in the device.

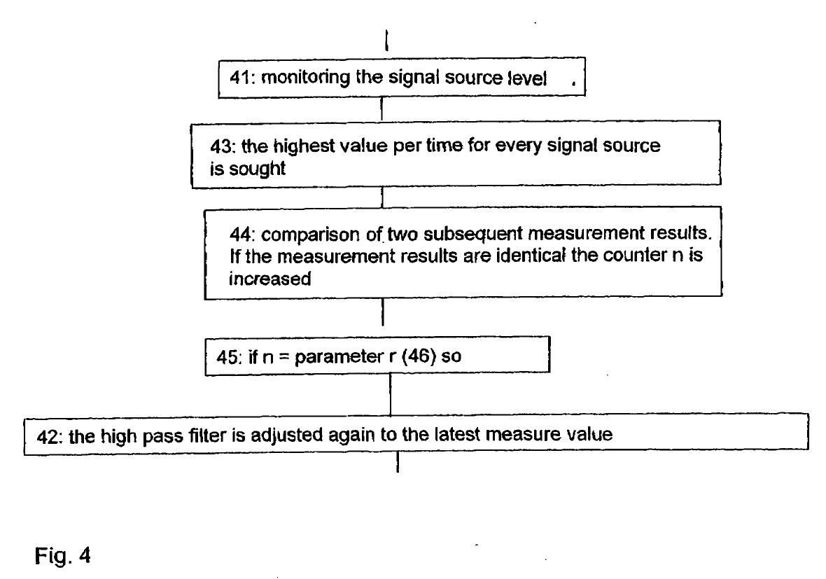

To a user and to the manufactures of the device is particularly hope worthy that, an algorithm adjusts the touching sensitivity, that is, the feel of the user, automatically into same even though the sensitivity of the film would weaken or that the surface films or plates with different thickness or material would be used is. More closely of the algorithm according to the invention is precised in the following and FIG. 4. The algorithm is constantly monitoring 41 the level of every touching area, for example a line or column that are signal sources and adjust a programmatic high pass filter 42 so that the sensors rest signal is filtered out. This is accomplished so that from the constant measuring data, a average is made to every signal source per time unit 43. The time unit can be parameterised when wanted. It is typical to the electret bubble film that the change of capacitivity when one presses the film is temporary. This makes it so that the averaged calculation result of two following time units for every signal source is not the same unless 44:
1. The sensor/s is/are in rest.
2. A unchangeable force is targeted to the sensor/s and the time has passed so much that the electret bubble film's capacitance has returned to rest.
3. A growing force that closely is corresponding the electret bubble film's capacitance change related to time is targeted to the sensor/s.

The high pass filter is adjusted so that exceeds with a parameterised marginal every level of signal source in the case 1. The case 1. Is separated from the cases 2. and 3. By taking advantage of the fact that human's muscle control is not precise comparing to the sensitivity of the electret bubble film. That is why the cases 2. and 3. only occur trough the statistic randomness. The probability of mistake choices that follows from this is adjustable 45 by changing the way of how the level of every signal sources of following time units has to be the same before the high pass filter is adjust. This number can be parameterised by the user 46 if wanted so that the user can adjust the feel exactly suitable for himself.

For example if the pad in question has 4 touching areas, a force can target two areas at a time and the best muscle control of the user creates a swift of 100 metering units, the possibility that the results of two following calculating result are the same and that the high pass filter adjust in wrong way, is about 1/10 000. When the amounts of time units is increased to three, is the possibility only about 1/ 1 000 000. With four time about units 1/ 100 000 000 and so on. If the high pass filter gets to be adjusted wrongly in a case like this, it is however usually adjusted too high and it hinders the detecting of force. Extra adjustments/presses won't slip to occur and the situation repairs itself the next time when the high pass filter adjusts. Typically the adjustment of high pass filter occurs several times per second. The adjustment made by the algorithm solves changes to the signals caused by both the ageing of the electret bubble film and other temporary changes. From this solution follows for example that if the sensors are given a smooth force producing factor, for example a artefact forgotten on the pad/adjuster, the pad adjusts after the time units so that the constant force filters out. This is an important feature considering the use of the device so that its use would be pleasant.

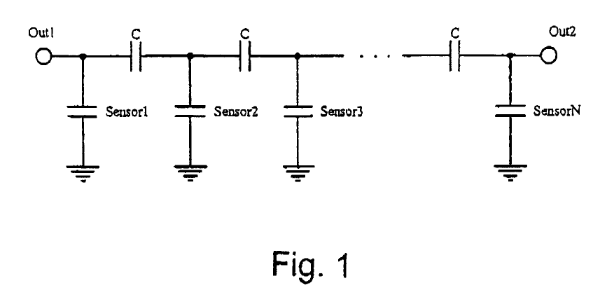

In the FIG. 1, a control unit's electrical switch according to the invention is depicted. The most essential matter is that sensor elements are capacitive connected to each other. Comparing to the traditional resistive connection (C=R) it brings many advantages such as a direct and circuit frequency response between the sensor elements. The biggest advantage related to the capacitance sensor is never the less that in the start ups charging amplifiers can directly be used. Also in these cases the location of the sensor can be figured out in the start ups in a direct relation for example with a pattern Out1/(Out1+Out2) regardless of the signal form. The accuracy is comparative to the relation C>> Csensor of the sensor elements and connection capacitors.

The connection can also be used so that lines are arranged vertically under the display and they are connected to each other in the previously described manner and the signals to the preamplifier are taken from the outer lines. After this horizontal lines are arranged under the display and the outer ones are again taken to the preamplifiers. With the help of these four different signals is easy to calculate what spot to press on the display or to which direction the finger should be moved. The advantage in a connection like this is specially that touching place's information can be calculated even though there occurs weakening in the sensitivity of the sensor material.

It is obvious to a person skilled in the art that the different find of applying methods of this invention do not limit them self only to the examples presented but they alter according to the claims presented later on. The invention can be applied and used in other dynamic pads such as piezo electrical.

1. An electromechanical control unit (12) that has keypad and/or touching base areas (102) to control the signal handling processing device,
in the control unit (12) there is a surface element (101),
by touching the surface element the changeable settings and values of the signal processing device's user are controlled,
there are solid and/or variable markings on the surface element's touching area (102) that when touching them with finger or a artefact and/or when sliding on them, the values of the changeable parameters of the signal-controlling unit can be controlled or value decisions are made,
which control unit is at least by part made of dynamic active material. A charge or voltage is created between the electrodes arranged on the surface of the material when the force targeted to it changes, the place and/or the amplitude being calculated with a microprocessor, micro controller or with a corresponding processor and with the received information the mentioned changeable parameter values being changed or value decisions are made,
characterised in that, it includes at least three or more sensor areas (108) and the areas reacting to the touching of the sensor areas (102), corresponding signal electrodes (106) are connected to each other with capacitor (110) and the areas connected to each other are connected to the preamplifiers at least from their outer areas (109).

2. The sensor matrix element according to the claim 1, characterised in that when pressing a singular spot, the place that has been pressed can be calculated from the signals seen in different sizes with the preamplifier because of the capacitor (110) and with this information the functions of the device can be directed in the wanted way.

3. The control unit according to the claim 1 characterised in that, according to the strength of the press the function of the pressed area can be influenced.

4. The device according to claim 1, characterised in that, that the devices batteries are charged with the electrical charge created between the electrodes (106, 105) on the outer surfaces of the sensor film when pressing.

5. The control unit according to the patent claim 1, characterised in that, the electro mechanical film (95) used in it is made of electret bubble film.

6. The control unit according to claim 1 that includes a micro controller, micro processor or another corresponding processor, characterised in that, a mathematical algorithm has been placed to the signal-processing unit in order to automatically adjust the feel of the touching base suitable to the user.

7. An electrical circuit according to the claim 6, characterised in that it includes a temperature calculating.

8. The control unit according to the claim 1, characterised in that, it is made of essentially thin and flexible material.

9. The control unit according to the claim 1, characterised in that, a display device has been placed on its outer surface.

10. The control unit according to the claim 1, characterised in that, the display device is made of thin and flexible material.

11. The control unit according to the claim 1, characterised in that, there are sensors in two lines that run to opposite directions and the sensor areas of both of the lines are long-like and together these opposite direction running sensor areas create a cross matrix figuration.

12. Electrical control unit (12) that has keypad and/or touching areas (102) to control the signal-controlling device,
in the control unit (12) there is a surface element (101)
the wanted settings and values that the user can change being controlled by touching the surface element,
there are touching areas (102) seen in the surface element that are equipped with solid and/or alternating markings, that when touching them with finger or with a artefact and/or when sliding on them, the values of the changeable parameters of the signal-controlling unit can be controlled or value decisions are made,
which control unit is at least by part made of layered structure that includes dynamic active material in to which a charge or voltage is created between the electrode surfaces in it as influence of touching and the place and/or the amplitude of it is calculated with a microprocessor, micro controller or with a corresponding processor and with the received information the mentioned changeable parameter values are changed or value decisions are made,
characterised in that the touching sensitivity is automatically adjusted suitable with the help of a mathematical algorithm placed in to the electronic circuit.

13. Electronic circuit according to the claim 12, characterised in that it has temperature calculation.

14. A mathematical algorithm according to the claim 12, characterised in that the algorithm is observing the level of every touching area's signal source continuously and adjusting the programmatic high pass filter in a way that the rest signal is filtered out. The filtering of the rest signal is achieved so that an average is made of the continuous calculation data for every signal source per time unit.

15. A mathematical algorithm according to the claim 14, characterised in that the time unit can be parameterised by the user.

16. An algorithm according to the claim 14, characterised in that the high pass filter is adjusted so that it exceeds every signal source's rest level with a parameterised marginal.
